(19) United States
(12) Patent Application Publication
(10) Pub. No.: US 2008/0085606 A1
(43) Pub. Date: Apr. 10, 2008

(54) Method for Fabricating a Structure for a Semiconductor Component, and Semiconductor Component

(76) Inventors: Dominik Fischer, Muenchen (DE); Werner Jacobs, Muenchen (DE); Daniel Koehler, Chemnitz (DE); Alfred Kersch, Putzbrunn (DE); Winfried Sabisch, Muenchen (DE)

Correspondence Address: SLATER & MATSIL, L.L.P., 17950 PRESTON ROAD, SUITE 1000, DALLAS, TX, 75252, US

(21) Appl. No.: 11/867,724

(22) Filed: Oct. 5, 2007

(30) Foreign Application Priority Data
Oct. 6, 2006 (DE) 10 2006 048 126.7
Apr. 25, 2007 (DE) 10 2007 020 547.5

(51) Int. Cl. H01L 21/461

(52) U.S. Cl. 438/736; 257/E21.486

(57) ABSTRACT

In one aspect, the invention provides a fabrication method. Before the fabrication of the structure, a mask layer, for example a hard mask, is applied to a layer. The mask layer has at least two layers composed of materials that can be etched selectively with respect to one another. In a first etching process, the structure is introduced into the layer. Subsequently, the first etching process is interrupted at a point in time in order to etch away a topmost layer of the hard mask selectively with respect to the underlying layer by means of a second etching process and, subsequently, the first etching process is continued for fabricating the structure with the new topmost layer.

This application claims priority to German Patent Application 10 2006 048 126.7, which was filed Oct. 6, 2006, and to German Patent Application No. 10 2007 020 547.5, which was filed Apr. 25, 2007, both of which applications are incorporated herein by reference.

### TECHNICAL FIELD

The present application relates to a method for fabricating a structure for a semiconductor component and a semiconductor component.

### BACKGROUND

The fabrication of semiconductor components often requires the patterning of layers and/or substrates, e.g., by means of dry etching methods using hard masks. Relatively long etching times are required precisely for the fabrication of deep structures, such as deep trench structures, and lead to an erosion of the hard masks used during etching. Typically, the cross section of the hard mask changes during the dry etching in such a way that it deviates from the desired form (e.g., circular or elliptical). The size changes as well, such that the fabricated structure deviates from the desired result both according to the form and according to the size.

### SUMMARY OF THE INVENTION

One embodiment of the invention provides a fabrication method. Before the fabrication of the structure, a mask layer, for example a hard mask, is applied to a layer. The mask layer has at least two layers composed of materials that can be etched selectively with respect to one another. In a first etching process, the structure is introduced into the layer. Subsequently, the first etching process is interrupted at a point in time in order to etch away a topmost layer of the hard mask selectively with respect to the underlying layer by means of a second etching process and, subsequently, the first etching process is continued for fabricating the structure with the new topmost layer.

By removing the respective topmost layer of the mask layer, in particular of the hard mask, it is ensured that a regenerated mask layer with a defined contour of the openings is present for the structure etching process.

### BRIEF DESCRIPTION OF THE DRAWINGS

The invention is explained in more detail below on the basis of a plurality of exemplary embodiments with reference to the figure of the drawings, in which:

FIG. 1A shows a schematic sectional view of the initial situation for a first embodiment of the method according to the invention with a two-layer hard mask;

FIG. 1B shows a schematic sectional view of the layer stack in accordance with FIG. 1A after a partial etching of the topmost layer of the hard mask and a partial patterning of a layer;

FIG. 1C shows a schematic sectional view of the layer stack in accordance with FIG. 1B after the removal of the topmost layer of the hard mask;

FIG. 1D shows a schematic sectional view of the layer stack in accordance with FIG. 1C after the continuation of the patterning of the layer;

FIG. 2A shows a schematic sectional view of the initial situation for a second embodiment of the method according to the invention with an n-layer hard mask;

FIG. 2B shows a schematic sectional view of the layer stack in accordance with FIG. 2A after a partial etching of the topmost layer of the hard mask and a partial patterning of a layer;

FIG. 2C shows a schematic sectional view of the layer stack in accordance with FIG. 2B after the removal of the topmost layer of the hard mask; and

FIG. 2D shows a schematic sectional view of the layer stack in accordance with FIG. 2C after the continuation of the patterning of the layer with a partly eroded new topmost layer of the hard mask.

### DETAILED DESCRIPTION OF ILLUSTRATIVE EMBODIMENTS

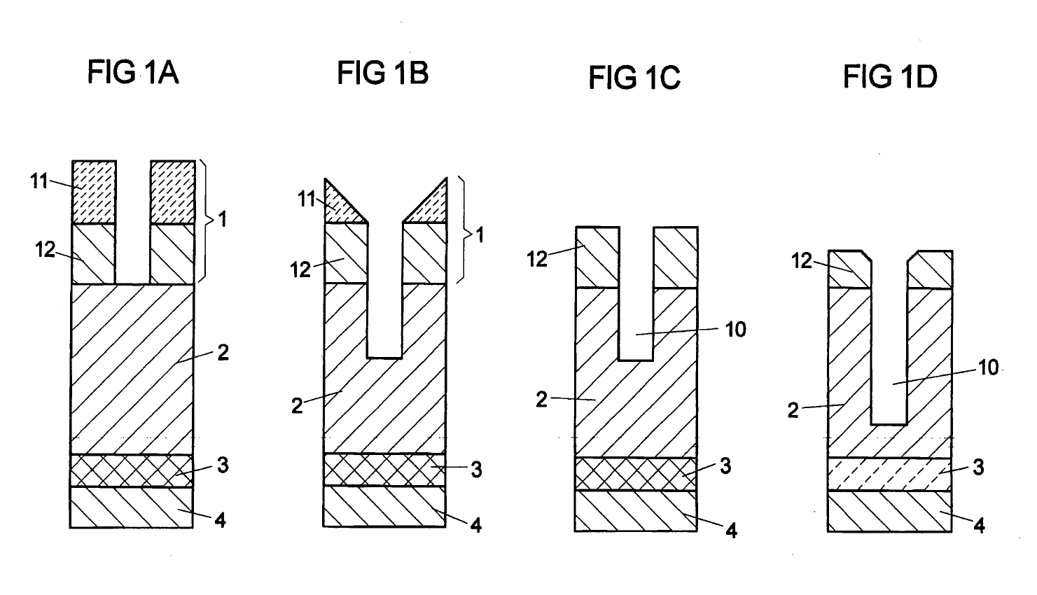

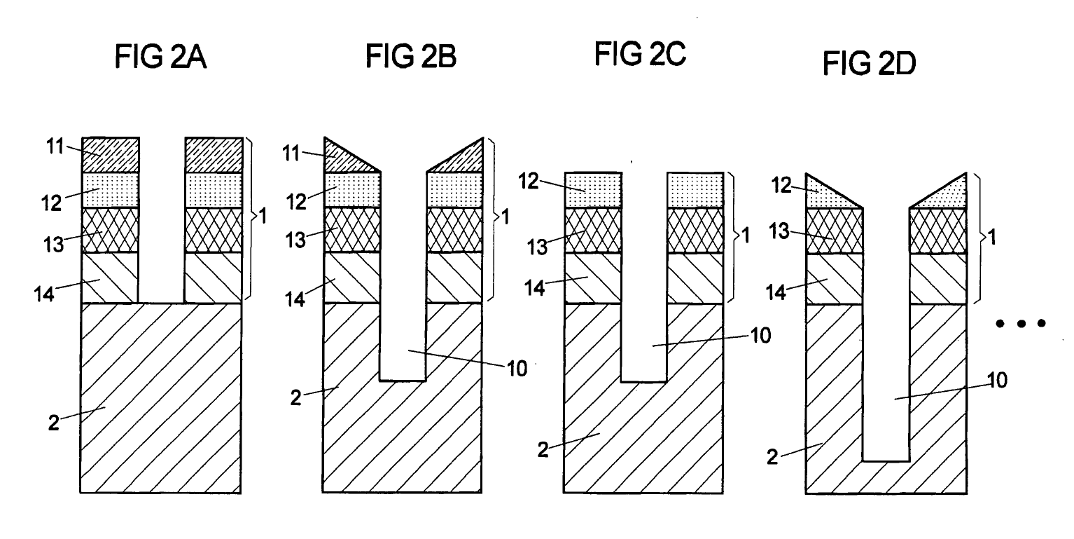

In the embodiments of the invention in accordance with FIGS. 1 and 2, reference is made to a patterning of a layer 2 by means of a hard mask 1.

The hard mask 1 is described here only as an example, which should not be understood as restrictive, of a mask layer 1. In principle, the mask layer 1 can also additionally or solely have a resist layer. Furthermore, the mask layer 1 can have at least one layer composed of an oxide, for example BSG or undoped USG, a silicon oxide, an aluminum oxide, for example A1₂O₃, a titanium oxide, a tungsten oxide, a nitride, a silicon nitride, an aluminum nitride, a titanium nitride, a tungsten nitride, a resist, carbon, ceramic, transition metal nitride, transition metal silicide, tungsten and/or polysilicon. It is also possible for at least one layer of the hard mask layer 1 to be doped with a species of an impurity atom.

The opening of the hard mask 1 in the present example defines the original image, which is imaged into a layer 2, e.g., by an anisotropic ion flow during a dry etching. The layer 2 is here a dielectric layer into which a deep trench structure 10 for a capacitor is to be introduced. By way of example, the dielectric layer is an oxide layer, in particular a BSG or USG layer, or a carbon layer.

In this case, the capacitor can have an electrode in cup or crown form. Even though the aspect ratios are smaller in the case of a cup or crown capacitor than in the case of a silicon deep trench, these capacitors are also among the deep trench structures.

In principle, however, other structures 10, in particular structures having high aspect ratios (e.g., greater than 20), can also be fabricated with the embodiments of the method. Further examples are contact holes through the dielectric layer or an opening for a mask.

The etching process for fabricating the structure 10 in the layer 2 is referred to as a first etching process in the embodiments described below. A SiN layer 3 and a silicon substrate 4 are additionally illustrated below the layer 2 in accordance with the embodiment in accordance with FIG. 1. In principle, however, for embodiments of the method it is unimportant what is arranged below the layer 2. Thus, the layer 2 can also already be a substrate (e.g., a wafer).

At the beginning of the first etching process, the opening is elliptical (or has some other specified form). The etching profile in the layer 2 assumes essentially this elliptical cross section and continues in the depth. In the course of the first etching process, however, the opening of the hard mask 1 is deformed by sputtering effects in such a way that the cross section approximates to a quadrangular form (or to a similar form defined by symmetry conditions). This is the case, e.g., whenever a plurality of structures is etched in direct proximity. The profile already imaged in the layer 2 remains essentially unaffected by the change in the mask opening.

The changed cross section of the opening now plays a part, however, for the further course of fabricating the structure. The elliptical cross section in the depth of the structure 10 to be fabricated is distilled. The disturbance deviates at any rate from the elliptical cross section sought and can even reveal a new mask opening cross section.

The embodiment of the method according to the invention makes it possible to permit the mask opening to assume the original form again in a late phase of the first etching process.

The mask opening thus has the desired form in the late phase of the etching process as well and the etching profile remains undisturbed in the depth. This reestablishment of the original form of the mask opening is also referred to as reconstruction.

The reconstruction can be realized, e.g., as follows. In the first embodiment, a hard mask is constructed as a stack comprising two materials (FIG. 1A) which can be etched selectively with respect to the layer 2 to be patterned. In principle, the hard mask 1 can have, e.g., layers composed of an oxide, carbon and/or polysilicon.

One example is a two-layer hard mask 1 having an upper layer 11 composed of carbon and an underlying layer 12 composed of polysilicon, as is illustrated in FIG. 1A. In FIG. 1A, this hard mask 1 has already been patterned in order to pattern the underlying layer 12, here a USG layer (USG undoped silicate glass). In this case, the materials of the two layers 11, 12 of the hard mask 1 are chosen such that one material can in each case be removed selectively with respect to all the others; in one embodiment in situ by means of a dry etching process. In the present example of FIG. 1A, the hard mask 1 has a layer 11 of carbon and a polysilicon layer 12, wherein the carbon can be removed in an oxygen plasma selectively with respect to the polysilicon and oxide.

After the commencement of the first etching process for fabricating the structure 2, the material in the topmost layer 11 of the hard mask 1 will be deformed, which is symbolized by the sloping surfaces in FIG. 1B; a mask erosion has commenced.

The first etching process is carried out using a CF plasma (mixture of CₓF_{y}H_{z} gases with a noble gas and/or O₂, CO, nitrogen oxide, etc.), by means of which the layer 2 composed of USG can be etched selectively with respect to the carbon of the first layer 11 and with respect to the polysilicon of the second layer 12 of the hard mask. Examples of CₓF_{y}H_{z} gases are C₄F₈, C₅F₈, C₄F₆, C₃F₅, CHF₃ CH₂F₂ and CH₄ i.e. y or z can, e.g., also be zero.

After a certain time, until a first depth has been reached, has elapsed, the first etching process is stopped and the deformed upper hard mask layer 11 is removed. This removal is effected by means of a second dry etching; here by means of an oxygen plasma that selectively removes the topmost layer 11 composed of carbon. It is possible in one embodiment for the second etching process to be carried out in situ in order that the interruption and continuation of the first etching process take up little time. In a further embodiment, the etching times of the etching processes are embodied proportionally to the layer thicknesses.

In principle, however it is also possible to remove layers 11, 12 of the hard mask by means of wet etching methods.

After the removal of the layers 11, 12, a layer stack in accordance with FIG. 1C is present, such that it is possible to continue the first etching process for fabricating the actual structure.

When the first etching process is continued, it is done with a mask opening having the desired form. The etching front in the depth remains undisturbed, and the desired profile can be fabricated as far as a second depth.

If a combination of a plurality of hard mask materials with the required properties exists, the mask reconstruction can be repeated again. This is illustrated in connection with FIG. 2. In principle, a layer stack is described which corresponds to that in FIGS. 1A to 1D, such that reference can be made to the corresponding description.

FIGS. 2A to 2D illustrate a further embodiment of a method according to the invention with a multilayer mask 1, the layers 11, 12, 13, 14 of which are composed of different materials. Only two double layers are illustrated here for reasons of clarity. In principle, the bottommost layer 14 can be one of n layers and the overlying layer 13 would then be the n−1-th layer.

The first etching process begins, wherein the topmost layer 11 is eroded (FIG. 2B). At a predetermined point in time, the topmost layer is stripped, e.g., in a dry or wet etching step (FIG. 2C), such that the second layer 12 forms the topmost layer. With the continuation of the first etching process, the second layer 12 is then also eroded, such that after a predetermined time this layer is stripped analogously to the method step in FIG. 2C. After two stripping steps for mask reconstruction, the third layer 13 is thus present as topmost layer. In a third stripping step, not actually illustrated here, the eroded third layer 13 is then removed in order to bring forth the fourth layer 14 with a sharp mask contour.

Given n mask layers 11, 12, 13, 14, a total of n−1 stripping steps will be necessary for mask reconstruction.

In a further embodiment of the method according to the invention, a substrate and/or a layer is patterned by means of the following steps:

depositing a mask stack 1 on the substrate and/or the layer, wherein the mask stack 1 has layers composed of at least two materials which are arranged one above another,

patterning the mask stack 1,

patterning the substrate and/or the layer by means of the mask stack 1, wherein during the processing a topmost layer (11) of the mask stack 1 is completely removed before an underlying layer 12 is incipiently etched in the direction perpendicular to the surface.

A further embodiment is a method for fabricating a structure 10, in particular having a high aspect ratio, comprising the following steps:

providing a substrate and/or layer;

depositing a first and a second hard mask layer 11, 12;

patterning the first and second hard mask layer 11, 12;

transferring the structure 10 from the hard mask layer 11, 12 into the substrate and/or the layer as far as a first depth; and

transferring the structure from the hard mask layer 11, 12 into the substrate and/or the layer as far as a second depth;

wherein between the steps of transferring the structure 10 as far as a first and as far as a second depth, the second hard mask layer 12 is completely removed at least in a vicinity around the structure 10 produced.

The embodiment of the invention is not restricted to the preferred exemplary embodiments specified above. Rather, a number of variants are conceivable which make use of the method according to the invention also in embodiments of different configuration, in principle. In particular, the materials of the hard mask layers can be chosen in the context of the required selectivities. Moreover, the etching methods mentioned here should be understood only by way of example and can be adapted to the technical requirements made of the products.

In principle, the method can be used in the fabrication of any desired semiconductor structures. Examples thereof are memory devices (e.g., DRAM, NROM, flash), optoelectronic components, microprocessors or microelectromechanical components (MEMS).

What is claimed is:

1. A method for fabricating an integrated circuit, the method comprising:
forming a mask layer over a region, wherein the mask layer comprises at least a first mask sublayer overlying a second mask sublayer, the first and second mask sublayers being composed of materials that can be etched selectively with respect to one another;
performing a first etching process to introduce a structure into the region;
interrupting the first etching process in order to perform a second etching process to etch away the first mask sublayer selectively with respect to the second mask sublayer; and
subsequently, continuing the first etching process to continue etching the structure in the region.

2. The method as claimed in claim 1, wherein the mask layer comprises a hard mask.

3. The method as claimed in claim 1, wherein the mask layer comprises more than two mask sublayers and wherein the interrupting and subsequently continuing the first etching process are repeated at least once.

4. The method as claimed in claim 1, wherein
the first mask sublayer comprises a material selected from the group consisting of BSG, undoped USG, silicon oxide, aluminum oxide, titanium oxide, tungsten oxide, silicon nitride, aluminum nitride, titanium nitride, tungsten nitride, resist, carbon, ceramic, transition metal nitride, transition metal silicide, tungsten and polysilicon;
the second mask sublayer comprises a material selected from the group consisting of BSG, undoped USG, silicon oxide, aluminum oxide, titanium oxide, tungsten oxide, silicon nitride, aluminum nitride, titanium nitride, tungsten nitride, resist, carbon, ceramic, transition metal nitride, transition metal silicide, tungsten and polysilicon; and
the material of the first mask sublayer is different than the material of the second mask sublayer.

5. The method as claimed in claim 4, wherein the first mask sublayer and/or the second mask sublayer is doped with a species of an impurity atom.

6. The method as claimed in claim 1, wherein the second etching process comprises a dry etching process.

7. The method as claimed in claim 1, wherein the second etching process is carried out in situ.

8. The method as claimed in claim 1, wherein etching times of the first and second etching processes are chosen proportionately to layer thicknesses of the first and second mask sublayers.

9. The method as claimed in claim 1, wherein the region comprises a dielectric layer.

10. The method as claimed in claim 9, wherein the dielectric layer comprises an oxide layer or a carbon layer.

11. The method as claimed in claim 1, wherein the structure comprises a trench-in-dielectric structure for a capacitor, a contact hole through a dielectric or an opening in a dielectric.

12. The method as claimed in claim 11, wherein the structure comprises an opening in a dielectric, the method further comprising forming a contact element between two metallization levels in the opening.

13. The method as claimed in claim 11, wherein the structure comprises a trench-in-dielectric structure for a capacitor, wherein the capacitor includes an electrode in the form of cup or crown arrangement.

14. The method as claimed in claim 1, wherein the structure has an aspect ratio of greater than 20.

15. The method as claimed in claim 1, wherein the first etching process comprises an anisotropic dry etching step.

16. The method as claimed in claim 1, wherein the structure has a circular, elliptical or polygonal cross section.

17. The method as claimed in claim 1, wherein the structure comprises a structure of a DRAM or an NROM.

18. The method as claimed in claim 1, wherein the mask layer is completely removed.

19. A semiconductor component fabricated according to the methods as claimed in claim 1.

20. A method of fabricating an integrated circuit, the method comprising:
depositing a mask stack over a substrate, wherein the mask stack comprises a plurality of layers composed of at least two materials, the layers being arranged one above another;
patterning the mask stack; and
patterning the substrate and/or a layer overlying the substrate using the patterned mask stack, wherein during the patterning a topmost layer of the mask stack is completely removed before an underlying layer is incipiently etched in a direction perpendicular to a surface of the substrate.

21. A method for fabricating a structure having a high aspect ratio, the method comprising:
providing a workpiece;
depositing a first hard mask layer over the workpiece;
depositing a second hard mask layer over the first hard mask layer;
patterning the first and second hard mask layers in the pattern of a structure;
transferring the structure from the first and second hard mask layers into the workpiece as far as a first depth;
after transferring the structure as far the first depth, completely removing the first hard mask layer; and
after completely removing the first hard mask layer, transferring the structure from the second hard mask layer into the workpiece as far as a second depth.

22. The method as claimed in claim 21, wherein the second depth is greater than 40 times a width of the structure.

23. The method as claimed in claim 21, further comprising:
depositing a third hard mask layer over the second hard mask layer, wherein patterning the first and second hard mask layers further comprises patterning the third hard mask layer;
completely removing the second hard mask layer after transferring the structure as far the second depth; and
transferring the structure from the third hard mask layer into the workpiece as far as a third depth after completely removing the second hard mask layer.

24. The method as claimed in claim 23, further comprising:
depositing a fourth hard mask layer over the third hard mask layer, wherein patterning the first and second hard mask layers further comprises patterning the fourth hard mask layer;
completely removing the third hard mask layer after transferring the structure as far the third depth; and
transferring the structure from the fourth hard mask layer into the workpiece as far as a fourth depth after completely removing the second hard mask layer.

25. The method as claimed in claim 24, wherein the structure comprises a memory device structure.
